(19) United States
(12) Patent Application Publication
(10) Pub. No.: US 2026/0191069 A1
(43) Pub. Date: Jul. 2, 2026

(54) HEAT TRANSFER COUPLER FOR SEMICONDUCTOR PACKAGE ASSEMBLY PROCESSES

(71) Applicant: Intel Corporation, Santa Clara, CA (US)

(72) Inventors: Phu Tuc NGUYEN, Ho Chi Minh City (VN); Ha Ngoc VU, Vung Tau City (VN); Long Thanh NGUYEN, Ho Chi Minh City (VN); Tan Ho Duy MAI, Ho Chi Minh City (VN); Prathamesh Bhalchandra VARTAK, Chandler, AZ (US); Anwar MOHIUDDIN, Maricopa, AZ (US); Mohan YASODHARABABU, Phoenix, AZ (US); Tin DO, Ho Chi Minh City (VN); Son Minh TRUONG, Ho Chi Minh City (VN); Anurag TRIPATHI, Gilbert, AZ (US)

(21) Appl. No.: 19/003,765

(22) Filed: Dec. 27, 2024

(51) Int. Cl. H01L 23/00

(52) U.S. Cl. CPC H10W 72/0711; H10W 72/072; H10W 72/07141; H10W 72/07178; H10W 72/07188; H10W 72/07232

(57) ABSTRACT

Heat transfer couplers, which can also be referred to as nozzles, for semiconductor manufacturing are provided. The heat transfer couplers include non-continuous channels on opposite faces. In an assembly process, semiconductor chips can be electrically coupled to a devices forming electrical interconnects. The assembly process can be a thermocompression bonding process in which first level interconnects are formed.

### FIELD

Descriptions are generally related to semiconductor manufacturing, and more particular descriptions are related to a coupler for heat transfer that can be used to, for example, transfer heat to create first level interconnects between a semiconductor chip and a package substrate.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor chips are typically “packaged” by attaching them to a package substrate that provides interconnections for power and signal input/output (IO). The package substrate can act as an interface between the semiconductor chip and other levels of interconnections, such as those for a socket interconnection or other types of interfaces or circuit board interconnections. The interconnections between a semiconductor chip and a package substrate can be considered first level interconnects (FLIs). Conductive interconnects, such as FLIs, can be created, for example, through thermal compression bonding (TCB) processes. A TCB process can use heat and mechanical pressure to create a metallurgical bond that forms the interconnections. A TCB process can create, for example, a copper to copper bond between bumps (or regions having other shapes) on the semiconductor chip and corresponding pads (or regions having other shapes) on the package substrate.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 illustrates an assembly that is useful for coupling a semiconductor die to a semiconductor package substrate using, for example, a thermocompression bonding (TCB) process.

FIGS. 2A-2C show a heat transfer coupler that can be used to manufacture semiconductor device assemblies.

FIGS. 3A-3B illustrate an arrangement of semiconductor dies and the arrangement projected on a heat transfer coupler.

FIG. 4 provides a method for manufacturing a semiconductor device assembly comprising semiconductor chip(s) and/or a package substrate.

FIG. 5 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Physical operations can be performed by semiconductor processing, assembly, and/or testing equipment, including computer systems that run testing recipes and protocols and operate aspects of the tools, equipment, and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, lithography, probing, material deposition (for example, chemical vapor deposition, atomic layer deposition, physical vapor deposition, electrodeposition, and/or sputtering), chemical mechanical planarization (CMP), and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass layers.

In further examples of a package substrate core, the substrate core is a glass core comprising one or more solid amorphous glass layers. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example.

Thermocompression bonding (TCB) processes can present challenges. For example, in multichip assemblies, flux ingestion into unwanted areas reduces tool part lifetimes and leads to stains on chip surfaces. Flux is commonly used to prepare metal surfaces for soldering by removing oxides, promoting wetting, and enhancing the flow of solder. Flux is dispensed onto a substrate surface before bonding processes to form electrical interconnects between chips and between chips and package substrates. Typically a solvent-soluble flux is used in TCB processes. As the temperature increases in a TCB bonding process, the flux can evaporate and contaminate surrounding parts. The temperature can increase to as much as 350° C. in some interconnect bonding processes. Flux accumulation can lead to faster heat transfer coupler (“nozzle”) failure during repeated manufacturing processes. Factors such as chip warpage, gaps between mold areas and a heat transfer coupler, and lower mold areas on chiplets (that lead to gaps between the mold area and the heat transfer coupler), lead to the escape of flux into unwanted areas.

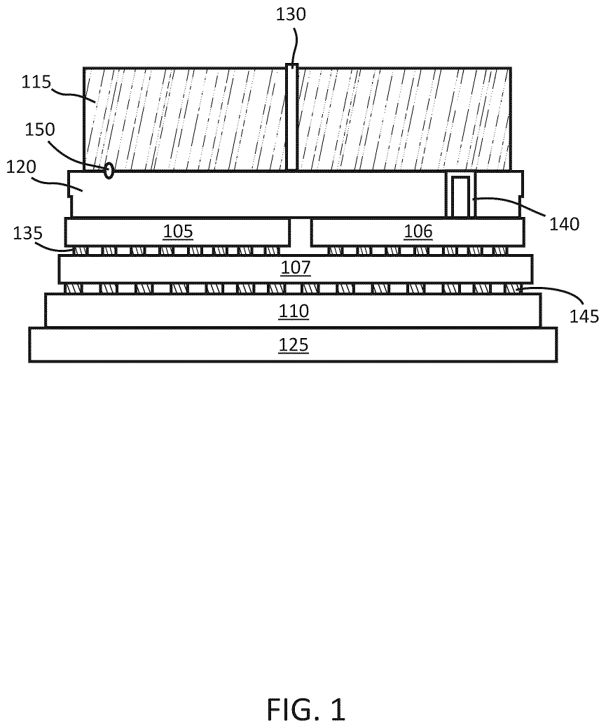

FIG. 1 illustrates a manufacturing assembly that is useful for a TCB process and an exemplary semiconductor chip package assembly in manufacturing assembly. The semiconductor chip package assembly includes semiconductor dies 105, 106, and 107, and a package substrate 110. The arrangement of the semiconductor dies 105, 106, and 107 can be considered a stacked configuration or a 3D configuration. Semiconductor die 107 can, for example, provide interconnects between dies 105 and 106. Other semiconductor chip package assemblies having other numbers of an arrangement of chips are possible. The manufacturing assembly includes a bond head heater 115 and a heat transfer coupler 120. Additional parts of a manufacturing tool or manufacturing system that are not shown can include, for example, mechanical systems for applying pressure so that the semiconductor dies 105 and 106 are pressed toward semiconductor die 107 and the package substrate 110. Additionally a manufacturing tool or manufacturing system can include vacuum systems that allow a vacuum to be applied through channels, such as, bond head heater channel(s) 130 and heat transfer coupler vias and channels 140. Other locations, sizes, and/or shapes are possible for bond head heater channel(s) 130 and coupler channels 140. The manufacturing assembly can also include a pedestal 125 that can be, for example, a vacuum pedestal that is adapted to holding a package substrate 110 during manufacturing processes. The bond head heater 115 can include one or more bond head heater channels 130 through which a vacuum can be applied. Bond head heaters 115 that are useful in TCB process systems can be, for example, multilayer composite stacks comprising a high conductivity ceramic material that includes heating traces. A high conductivity ceramic material can be aluminum nitride and the heating traces can be comprised of tungsten. A heat transfer coupler 120 can also be referred to as a nozzle or a thermal compression bonding nozzle. The heat transfer coupler 120 includes coupler channels 140 and connected vacuum trenches (not shown in FIG. 1). A vacuum can be applied through coupler channels 140 and vacuum trenches. A vacuum applied through coupler channels 140 and vacuum trenches can secure the semiconductor dies 105 and 106 to a surface of heat transfer coupler 120.

A TCB process can form conductive interconnects 135 and 145 between chips 105 and 106 and chip 107, and/or chip 107 and a package substrate 110. Conductive interconnects 135 and/or 145 can be ones that are formed through the application of heat or the application of heat and mechanical pressure. The conductive interconnects 135 and/or 145 can comprise, for example, gold, copper, silver, bismuth, lead nickel, aluminum, solder, and/or conductive adhesives. The conductive interconnects 135 and/or 145 that are formed can be a physical join between a bump, a pin, a rod, a solder region, a conductive adhesive region, or other shaped region, and a rod, a pad, or other shaped region. The conductive interconnects 135 and/or 145 can be formed, for example, using a bonding process that is controlled collapse chip connection (C4) or flip chip process. Additionally, the conductive interconnects 135 and/or 145 can be formed using a hybrid bonding process. A connection process can alternatively employ a bump shaped conductive region and a conductive adhesive to form the conductive interconnects 135 and/or 145.

Heat transfer coupler 120 can also optionally include an alignment feature 150 that mates with a corresponding feature on the bond head heater 115. The alignment feature 150 can have any shape, and can be, for example, a cavity that a protrusion on the bond head heater 115 fits into or can be a protrusion that fits into a cavity on the bond head heater 115. Alternatively, the alignment feature 150 can be a mark or pattern that is detectable by a camera associated with the bond head heater 115.

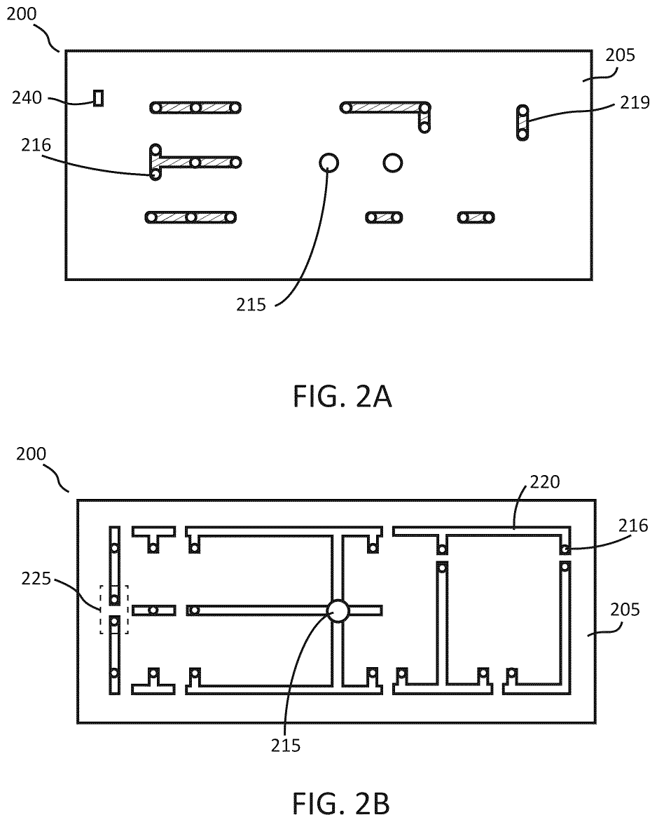

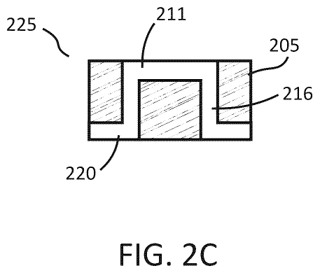

FIGS. 2A-2C provide an exemplary heat transfer coupler that can be used in manufacturing processes in which interconnects are formed that electrically couple semiconductor dies together, electrically couple semiconductor dies to an active interposer, an interposer, and/or electrically couple semiconductor die(s) to a package substrate. The heat transfer coupler of FIGS. 2A-2C can be, for example the heat transfer coupler 120 of FIG. 1. A first side of the heat transfer coupler 200 (depicted in FIG. 2A) includes a solid body 205 and first vacuum trenches 219, second vacuum trenches 211, first vacuum vias 215, second vacuum vias 216, and vacuum trenches 219 in the solid body 205. The first side of the heat transfer coupler 200 can contact a face of a bond head heater (not shown in FIG. 2A), such as bond head heater 115 which can be one, for example, as shown in and described with respect to FIG. 1. The solid body 205 of the heat transfer coupler can be comprised of a thermally conductive material, such as, for example, a metallic material, such as, copper, aluminum, or alloys thereof, and/or one or more layers or coatings of the foregoing materials. Alternatively, the solid body 205 of the heat transfer coupler can be comprised of a ceramic material, such as silicon carbide (SiC), aluminum nitride (AlN), titanium nitride, or diamond. The diamond can be comprised of diamond material, such as a material that was created through a chemical vapor deposition (CVD) process. Other materials are also possible. The heat transfer coupler 200 can also optionally include an alignment feature 240 that can be, for example, a pattern or shape that can be read or detected by a camera associated with a bond head heater or protrusion or a cavity that can mate with a feature on a bond head heater.

The second side of heat transfer coupler 200 (depicted in FIG. 2B) can contact a face of one or more semiconductor chips, such as the semiconductor chips 105 and 106 of FIG. 1. The chip-facing side of the heat transfer coupler 200 includes vacuum trenches 220 and vacuum vias 215 and 216. FIG. 2C is an expanded cut-through section of the region 225 outlined in a dashed line.

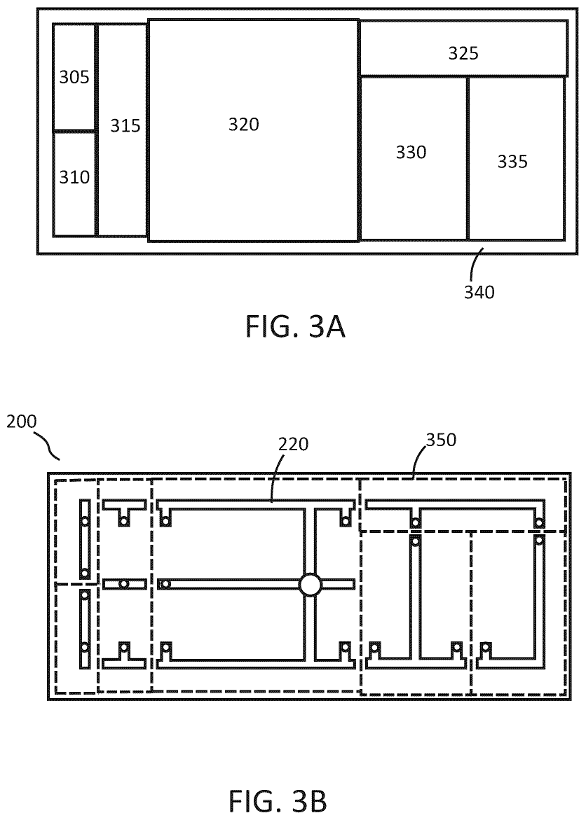

FIG. 3A shows an exemplary layout of a multichip package (MCP). Semiconductor chips 305, 310, 315, 320, 325, 330, and 335 can be stacked on an additional device 340 that can be a semiconductor chip, an interposer, an active interposer (such as one comprising interconnections and logic), or a package substrate. FIG. 3B illustrates the outlines (shown as dashed lines 350) of the semiconductor chips 305, 310, 315, 320, 325, 330, and 335 for the arrangement shown in FIG. 3A superimposed over the heat transfer coupler 200 of FIG. 2B. As can be seen, the non-continuous nature of the vacuum channels 220 on the die-facing side means that no vacuum channel 220 intersects with an edge of a semiconductor chip. Other designs are possible and desirable for arrangements of semiconductor chips that are different than the example provided here.

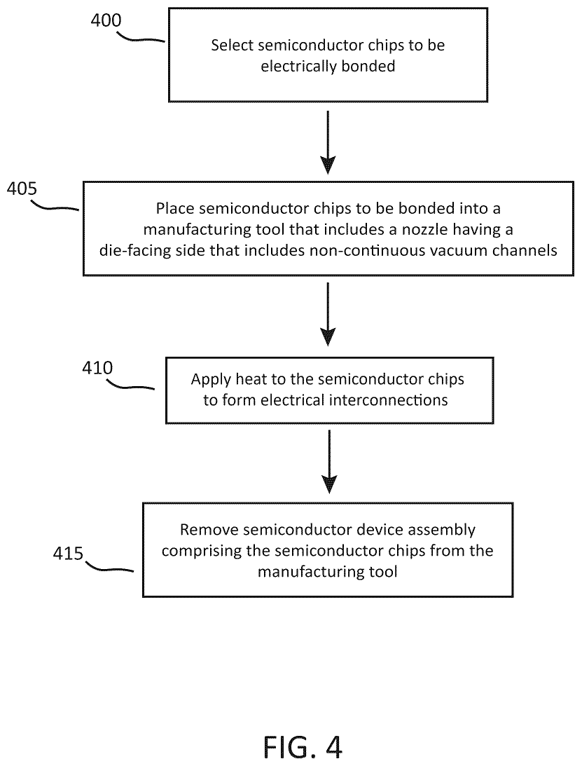

FIG. 4 diagrams a method for manufacturing an assembly comprising semiconductor chips. In FIG. 4, one or more semiconductor chips that are to be functionally electrically coupled to another device (e.g., semiconductor chip, active interposer, interposer, or a package substrate) are selected (400). The semiconductor chips are placed in a manufacturing tool (405). The manufacturing tool can comprise one or more heat transfer couplers as shown and described herein with respect to FIGS. 1, 2A-2C, and/or 3A-3B. Heat can be applied through the heat transfer coupler to form electrical connections between the semiconductor chips and another device (410). The semiconductor chips can comprise bumps, pads, pins, or solder regions that are joined to a corresponding region on the other device (such as a bump, pad, pin, or solder region) through the manufacturing process. The manufacturing process can be a TCB process in which a metallurgical bond is formed between metal regions on the semiconductor chip and metal regions on the package substrate. The metal regions can be comprised of, for example, copper, tin, bismuth, lead, nickel, or an alloy of one or more of the foregoing. The manufacturing process can additionally comprise the application of pressure the semiconductor chips and other device to cause the formation of electrical connections. A TCB compression process typically employs a linear motor that operates with precision and accuracy and that can move in a compression direction with precision. An assembly comprising semiconductor chips and other device, where the semiconductor chips are operably coupled to the device can be removed from the manufacturing tool (415).

A manufacturing tool can additionally comprise a vacuum supply system, in which vacuum can be applied to the heat transfer coupler and/or to a vacuum pedestal. The heat transfer coupler can hold a semiconductor chip in place during the manufacturing process through the application of a vacuum. The pedestal can hold a package substrate in place through the application of a vacuum.

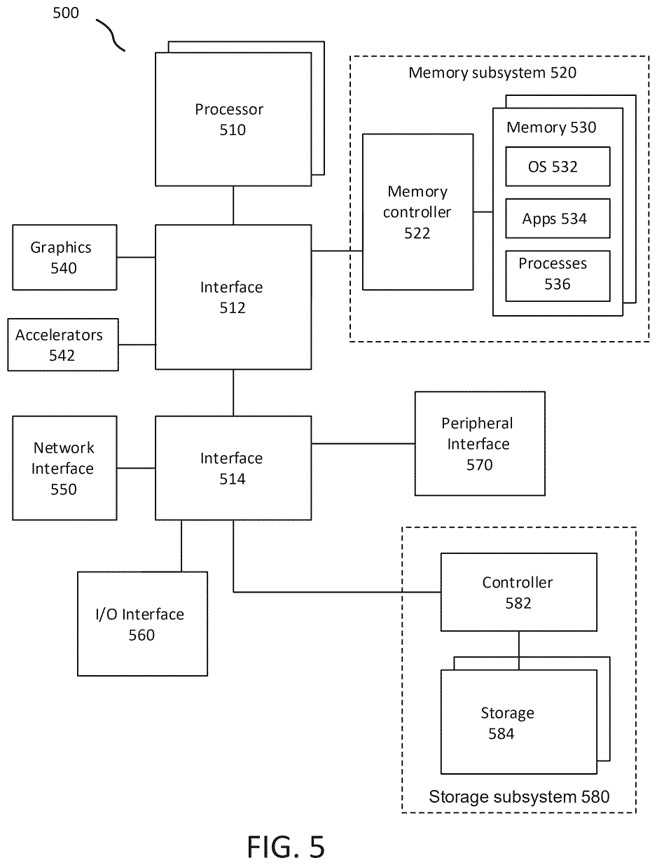

In FIGS. 1, 2A-2C, 3A-3B, and 4 the semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), active interposers, interposers, HBM, and/or other memory devices. These semiconductor chip packages can be heterogeneous packages that incorporate different types of chips into one package. The semiconductor chips can be any of the chips, for example, described herein with respect to FIG. 5. The semiconductor chip packages described herein generally can be part of various larger package structures and configurations and the foregoing examples are not meant to limit the types of assemblies that are possible.

FIG. 5 depicts an example computing system. The computing system can be a system used for running equipment in a semiconductor fabrication plant. For example, instructions for operating assembly and manufacturing tools, or for performing one or more aspects of or recipes associated with the process described in FIG. 4 can be stored and/or run on the computing system. A computing system 500 can include more, different, or fewer features than the ones described with respect to FIG. 5.

Computing system 500 includes processor 510, which provides processing, operation management, and execution of instructions for system 500. Processor 510 can include any type of microprocessor, CPU (central processing unit), GPU (graphics processing unit), processing core, or other processing hardware to provide processing for system 500, or a combination of processors or processing cores. Processor 510 controls the overall operation of system 500, and can be or include, one or more programmable general-purpose or special-purpose microprocessors, DSPs, programmable controllers, ASICs, programmable logic devices (PLDs), or the like, or a combination of such devices.

In one example, system 500 includes interface 512 coupled to processor 510, which can represent a higher speed interface or a high throughput interface for system components needing higher bandwidth connections, such as memory subsystem 520 or graphics interface components 540, and/or accelerators 542. Interface 512 represents an interface circuit, which can be a standalone component or integrated onto a processor die. Where present, graphics interface 540 interfaces to graphics components for providing a visual display to a user of system 500. In one example, the display can include a touchscreen display.

Accelerators 542 can be a fixed function or programmable offload engine that can be accessed or used by a processor 510. For example, an accelerator among accelerators 542 can provide data compression (DC) capability, cryptography services such as public key encryption (PKE), cipher, hash/authentication capabilities, decryption, or other capabilities or services. In some cases, accelerators 542 can be integrated into a CPU socket (e.g., a connector to a motherboard (or circuit board, printed circuit board, mainboard, system board, or logic board) that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 530 stores and hosts, among other things, operating system (OS) 532 that provides a software platform for execution of instructions in system 500, and stores and hosts applications 534 and processes 536. In one example, memory subsystem 520 includes memory controller 522, which is a memory controller to generate and issue commands to memory 530. The memory controller 522 can be a physical part of processor 510 or a physical part of interface 512. For example, memory controller 522 can be an integrated memory controller, integrated onto a circuit within processor 510.

System 500 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 500 includes interface 514, which can be coupled to interface 512. In one example, interface 514 represents an interface circuit, which can include standalone components and integrated circuitry. In one example, user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB, or other wired or wireless standards-based or proprietary interfaces. Network interface 550 can transmit data to a device that is in the same data center or rack or a remote device, which can include sending data stored in memory.

Some examples of network interface 550 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include additional types of hardware interfaces, such as, for example, interfaces to semiconductor fabrication equipment and/or electrostatic charge management devices.

In one example, system 500 includes storage subsystem 580. Storage subsystem 580 includes storage device(s) 584, which can be or include any conventional medium for storing data in a nonvolatile manner, such as one or more magnetic, solid state, and/or optical based disks. Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 512 or processor 510 or can include circuits or logic in both processor 510 and interface 514.

A power source (not depicted) provides power to the components of system 500. More specifically, power source typically interfaces to one or multiple power supplies in system 500 to provide power to the components of system 500.

Examples of systems may be implemented in various types of computing, smart phones, tablets, personal computers, and networking equipment, such as switches, routers, racks, and blade servers such as those employed in a data center and/or server farm environment.

### EXAMPLES

A system can comprise: a heat transfer coupler comprising a first face and a second face, wherein the first face is opposite the second face, wherein the heat transfer coupler comprises first non-continuous channels in the first face, wherein the heat transfer coupler comprises second non-continuous channels in the second face, and wherein a plurality of vias interconnect the first non-continuous channels with the second non-continuous channels; a pedestal wherein the pedestal is capable of reversibly attaching a device to which semiconductor chips are to be bonded; and a heater wherein the heater is capable of supplying heat to the first face of the heat transfer coupler to cause conductive interconnections to be formed between a semiconductor chip attached to the second face and a device attached to the pedestal. The device can be a semiconductor chip, an active interposer, an interposer, or a package substrate. The heat transfer coupler additionally can comprise an alignment feature that mates with a corresponding feature of a face of the heater. The heat transfer coupler additionally can comprise an alignment feature wherein the alignment feature is a cavity or a protrusion. The pedestal can be a vacuum pedestal and the pedestal can be capable of reversibly attaching a device through application of a vacuum to a surface of the device. The second non-continuous channels in the second face can be capable of reversibly attaching a semiconductor chip when a vacuum is applied through second non-continuous channels. The heat transfer coupler can be comprised of a metallic material. The heat transfer coupler can be comprised of a ceramic material. The heat transfer coupler can be comprised of silicon carbide, aluminum nitride, titanium nitride or diamond.

A device can comprise: a body comprising a solid material wherein the body has a first face that is opposite a second face; first non-continuous channels in the first face; second non-continuous channels in the second face; and a plurality of vias that interconnect the first non-continuous channels with the second non-continuous channels. The body additionally can comprise an alignment feature. The body additionally can comprise an alignment feature and the alignment feature is to be detected by a camera. The body can be comprised of a metallic material. The body can be comprised of a ceramic material. The body can be comprised of silicon carbide, aluminum nitride, titanium nitride, or diamond. The second non-continuous channels can be capable of reversibly holding a semiconductor chip.

A method can comprise: placing a substrate and semiconductor chips that are to be electrically coupled in a manufacturing tool wherein the manufacturing tool comprises: a heater, and a heat transfer coupler comprising a first face and a second face, wherein the first face is opposite the second face, wherein the heat transfer coupler comprises first non-continuous channels in the first face, wherein the heat transfer coupler comprises second non-continuous channels in the second face, wherein a plurality of vias interconnect the first non-continuous channels with the second non-continuous channels, wherein semiconductor chips are attached to the second face through a vacuum applied through the second non-continuous channels, and wherein the second non-continuous channels do not cross an edge of the semiconductor chips; and applying heat to the first face of the heat transfer coupler, to cause electrical connections to be formed between the semiconductor chip and the substrate. The manufacturing tool can be capable of applying mechanical pressure and the electrical connections can be also formed through application of mechanical pressure. The heat transfer coupler additionally can comprise an alignment feature that can be detected by a camera. The heat transfer coupler can be comprised of a metallic material or a ceramic material.

Besides what is described herein, various modifications can be made to what is disclosed and implementations without departing from their scope. Therefore, the illustrations and examples herein should be construed in an illustrative, and not a restrictive sense.

What is claimed is:

1. A system comprising:
a heat transfer coupler comprising a first face and a second face, wherein the first face is opposite the second face, wherein the heat transfer coupler comprises first non-continuous channels in the first face, wherein the heat transfer coupler comprises second non-continuous channels in the second face, and wherein a plurality of vias interconnect the first non-continuous channels with the second non-continuous channels;
a pedestal wherein the pedestal is capable of reversibly attaching a device to which semiconductor chips are to be bonded; and
a heater wherein the heater is capable of supplying heat to the first face of the heat transfer coupler to cause conductive interconnections to be formed between a semiconductor chip attached to the second face and a device attached to the pedestal.

2. The system of claim 1 wherein the device is a semiconductor chip, an active interposer, an interposer, or a package substrate.

3. The system of claim 1 wherein the heat transfer coupler additionally comprises an alignment feature that mates with a corresponding feature of a face of the heater.

4. The system of claim 1 wherein the heat transfer coupler additionally comprises an alignment feature and the alignment feature is a cavity or a protrusion.

5. The system of claim 1 wherein the pedestal is a vacuum pedestal and the pedestal is capable of reversibly attaching a device through application of a vacuum to a surface of the device.

6. The system of claim 1 wherein the second non-continuous channels in the second face are capable of reversibly attaching a semiconductor chip when a vacuum is applied through second non-continuous channels.

7. The system of claim 1 wherein the heat transfer coupler is comprised of a metallic material.

8. The system of claim 1 wherein the heat transfer coupler is comprised of a ceramic material.

9. The system of claim 1 wherein the heat transfer coupler is comprised of silicon carbide, aluminum nitride, titanium nitride, or diamond.

10. A device comprising:
a body comprising a solid material wherein the body has a first face that is opposite a second face;
first non-continuous channels in the first face;
second non-continuous channels in the second face; and
a plurality of vias that interconnect the first non-continuous channels with the second non-continuous channels.

11. The device of claim 10 wherein the body additionally comprises an alignment feature.

12. The device of claim 10 wherein the body additionally comprises an alignment feature and the alignment feature is to be detected by a camera.

13. The device of claim 10 wherein the body is comprised of a metallic material.

14. The device of claim 10 wherein the body is comprised of a ceramic material.

15. The device of claim 10 wherein the body is comprised of silicon carbide, aluminum nitride, titanium nitride, or diamond.

16. The device of claim 10 wherein the second non-continuous channels are capable of reversibly holding a semiconductor chip.

17. A method comprising:
placing a substrate and semiconductor chips that are to be electrically coupled in a manufacturing tool wherein the manufacturing tool comprises:
a heater, and
a heat transfer coupler comprising a first face and a second face, wherein the first face is opposite the second face, wherein the heat transfer coupler comprises first non-continuous channels in the first face, wherein the heat transfer coupler comprises second non-continuous channels in the second face, wherein a plurality of vias interconnect the first non-continuous channels with the second non-continuous channels, wherein semiconductor chips are attached to the second face through a vacuum applied through the second non-continuous channels, and wherein the second non-continuous channels do not cross an edge of the semiconductor chips; and
applying heat to the first face of the heat transfer coupler, to cause electrical connections to be formed between the semiconductor chip and the substrate.

18. The method of claim 17 wherein the manufacturing tool is capable of applying mechanical pressure and wherein the electrical connections are also formed through application of mechanical pressure.

19. The method of claim 17 wherein the heat transfer coupler additionally comprises an alignment feature that can be detected by a camera.

20. The method of claim 17 wherein the heat transfer coupler is comprised of a metallic material or a ceramic material.
